(19) United States
(12) Patent Application Publication
(10) Pub. No.: US 2023/0253521 A1
(43) Pub. Date: Aug. 10, 2023

(54) SOLAR CELL MANUFACTURE

(71) Applicant: SEMCO SMARTECH FRANCE, CASTRIES (FR)

(72) Inventors: Juhong YANG, CASTRIES (FR); Raymond DE MUNNIK, CASTRIES (FR)

(21) Appl. No.: 18/003,044

(22) PCT Filed: Jul. 12, 2021
(86) PCT No.: PCT/EP2021/069368

§ 371 Date: Dec. 22, 2022

(30) Foreign Application Priority Data
Jul. 13, 2020 (FR) 2007380
Oct. 28, 2020 (FR) 2011025

(51) Int. Cl. H01L 31/18; H01L 31/0352

(52) U.S. Cl. CPC H01L 31/18; H01L 31/035281

(57) ABSTRACT

The present disclosure relates to a method of manufacturing a solar cell, the method comprising, in the order:
forming a tunnel oxide (52) over, at least, one surface of a semiconductor substrate (50);
forming a layer doped with a first-type conductive dopant over the tunnel oxide;
forming a mask (56) on the doped layer; and
performing, in a gas atmosphere (62) containing a second-type conductive dopant, doping at least one first region (66) of the doped layer using a laser.

This application claims the priorities of French patent applications number 2007380, filed on Jul. 13, 2020, entitled “formation de contacts passives pour cellules solaires IBC” and number 2011028, filed on Oct. 28, 2020, entitled “Fabrication de cellules solaires”, the contents of which are incorporated by reference to the maximum extent allowable by law.

### TECHNICAL FIELD

The present disclosure relates generally to solar cells and more particularly to back side contact solar cell structures and manufacturing process.

### BACKGROUND ART

Solar cells are devices for converting sunlight into electrical energy. Generally, solar cells structure is based on the presence of p-type region and n-type region on the same semiconductor substrate. In a back side contact solar cell, each region is coupled to metal contacts on the back side of the solar cells to allow an external electrical circuit or device to be coupled to and be powered by the solar cell as described in US2016/0351737 and in US7468485.

### SUMMARY OF INVENTION

There is a need to improve current solar cells and the manufacturing process of the current solar cells, particularly to decrease the process time.

One embodiment addresses all or some of the drawbacks of known solar cells and their process of manufacturing.

One embodiment provides a method of manufacturing a solar cell, the method comprising, in the order:
forming a tunnel oxide over, at least, one surface of a semiconductor substrate;
forming a layer doped with a first-type conductive dopant over the tunnel oxide;
forming a mask on the doped layer; and
performing, in a gas atmosphere containing a second-type conductive dopant, doping at least one first region of the doped layer using a laser.

According to an embodiment, the method comprises forming trenches extending in the mask, the tunnel oxide and the doped layer, after the formation of the mask.

According to an embodiment, trenches separate the first regions of the doped layer from second regions of the doped layer.

According to an embodiment, the gas includes phosphoryl chloride.

According to an embodiment, the method comprises texturing of the semiconductor substrate on another surface.

According to an embodiment, the method comprises forming a passivation film over the doped layer, the passivation layer recovering the inside of trenches.

One embodiment provides an interdigited-back-contact or IBC solar cell obtained by the method described above.

One embodiment provides a solar panel comprising interdigited-back-contact solar cells.

### BRIEF DESCRIPTION OF DRAWINGS

The foregoing features and advantages, as well as others, will be described in detail in the following description of specific embodiments given by way of illustration and not limitation with reference to the accompanying drawings, in which:

FIG. 1 illustrates a sectional view illustrating an example of a solar cell;

FIG. 2 illustrates a sectional view illustrating a step of an example of method of manufacturing the solar cell illustrated in FIG. 1;

FIG. 3 illustrates another step of the manufacturing method of FIG. 2;

FIG. 4 illustrates another step of the manufacturing method of FIG. 2;

FIG. 5 illustrates another step of the manufacturing method of FIG. 2;

FIG. 6 illustrates another step of the manufacturing method of FIG. 2;

FIG. 7 illustrates another step of the manufacturing method of FIG. 2;

FIG. 8 illustrates another step of the manufacturing method of FIG. 2;

FIG. 9 illustrates another step of the manufacturing method of FIG. 2;

FIG. 10 illustrates another step of the manufacturing method of FIG. 2;

FIG. 11 illustrates another step of the manufacturing method of FIG. 2;

FIG. 12 illustrates another step of the manufacturing method of FIG. 2;

FIG. 13 illustrates another step of the manufacturing method of FIG. 2;

FIG. 14 illustrates another step of the manufacturing method of FIG. 2;

FIG. 15 illustrates another step of the manufacturing method of FIG. 2;

FIG. 16 illustrates another step of the manufacturing method of FIG. 2;

FIG. 17 illustrates a sectional view illustrating a solar cell in accordance with an embodiment of the present description;

FIG. 18 illustrates a sectional view illustrating a step of a method of manufacturing a solar cell in accordance with the embodiment of the present description;

FIG. 19 illustrates another step of the manufacturing method of FIG. 18;

FIG. 20 illustrates another step of the manufacturing method of FIG. 18;

FIG. 21 illustrates another step of the manufacturing method of FIG. 18;

FIG. 22 illustrates another step of the manufacturing method of FIG. 18;

FIG. 23 illustrates another step of the manufacturing method of FIG. 18;

FIG. 24 illustrates another step of the manufacturing method of FIG. 18;

FIG. 25 illustrates another step of the manufacturing method of FIG. 18;

FIG. 26 illustrates another step of the manufacturing method of FIG. 18;

FIG. 27 illustrates another step of the manufacturing method of FIG. 18;

FIG. 28 illustrates another step of the manufacturing method of FIG. 18;

FIG. 29 illustrates another step of the manufacturing method of FIG. 18; and

FIG. 30 illustrates another step of the manufacturing method of FIG. 18;

### DESCRIPTION OF EMBODIMENTS

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10%, and preferably within 5%.

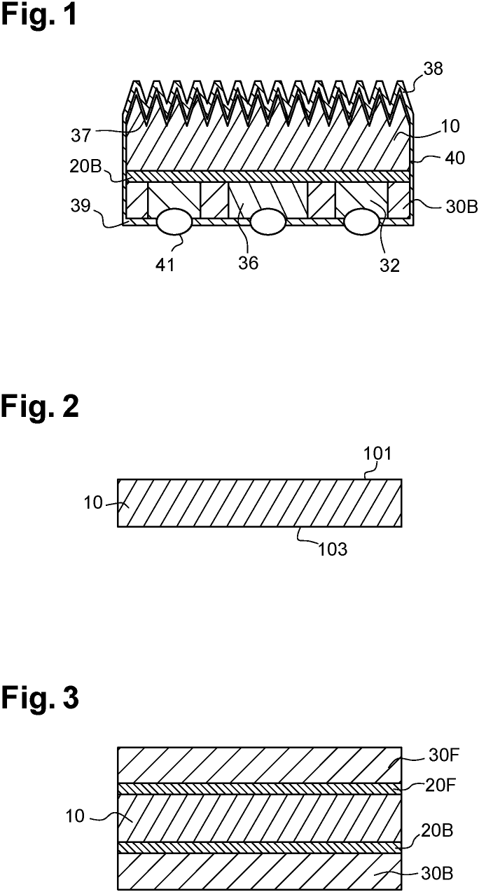

FIG. 1 is a sectional view illustrating an example of a solar cell.

The solar cell shown in FIG. 1 is made of a semiconductor substrate 10 having a front side portion intended to receive solar radiation during normal operation and a back side portion where metal contacts of the solar cell are formed. The solar cell has a textured front side covered by a doped layer 37.

The solar cell of FIG. 1 includes first regions 32 of a first type of conductivity, such as p-type regions, and second regions 36 of a second type of conductivity, such as n-type regions, formed in an undoped layer 30B over the back side of the substrate 10. A tunnel oxide layer 20B may be formed on the back side of the substrate 10, more precisely, between the substrate 10 and the undoped layer 30B. Layer 37 is of the second type of conductivity.

Metal contacts 41 are connected to regions 32 and 36 to allow external circuits and devices to receive electrical power from the solar cell.

Solar cell of FIG. 1 may include passivation layers 38, 39, 40 to protect the structure from outside electrical damages.

FIGS. 2 to 16 are sectional views illustrating steps of an example of method of manufacturing the solar cell illustrated in FIG. 1.

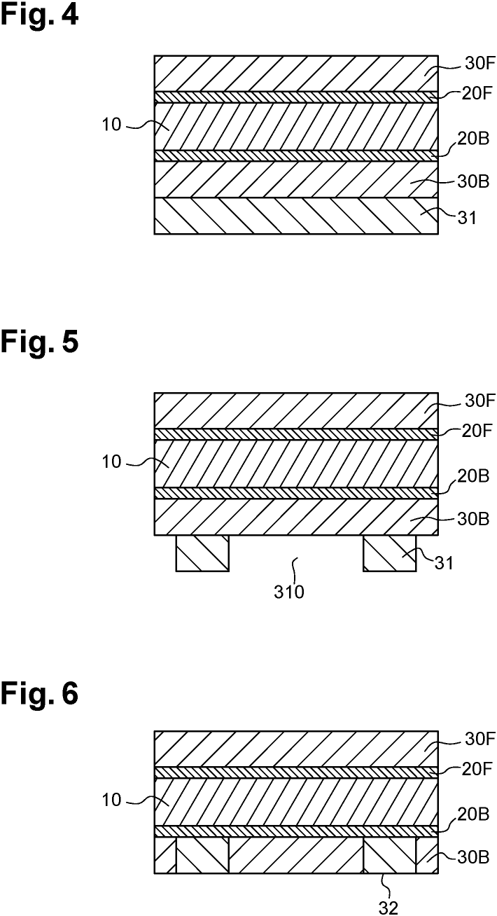

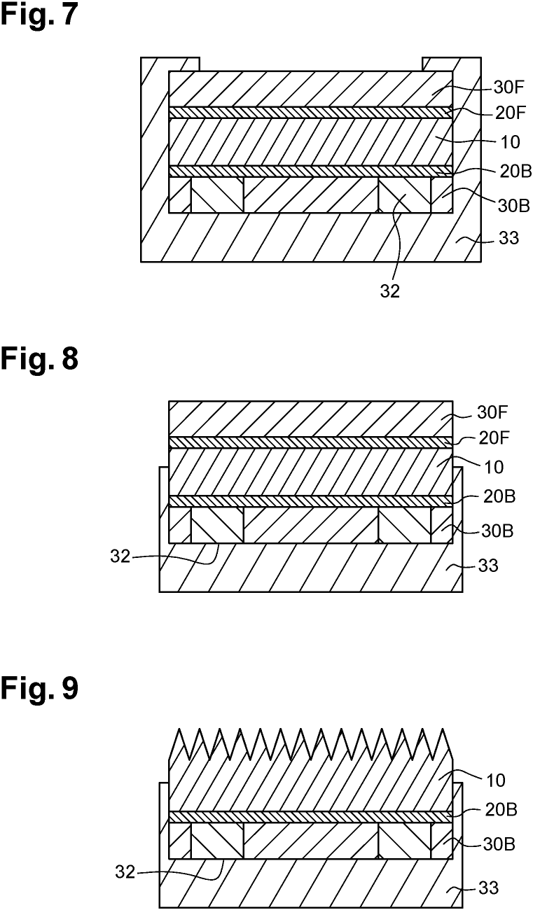

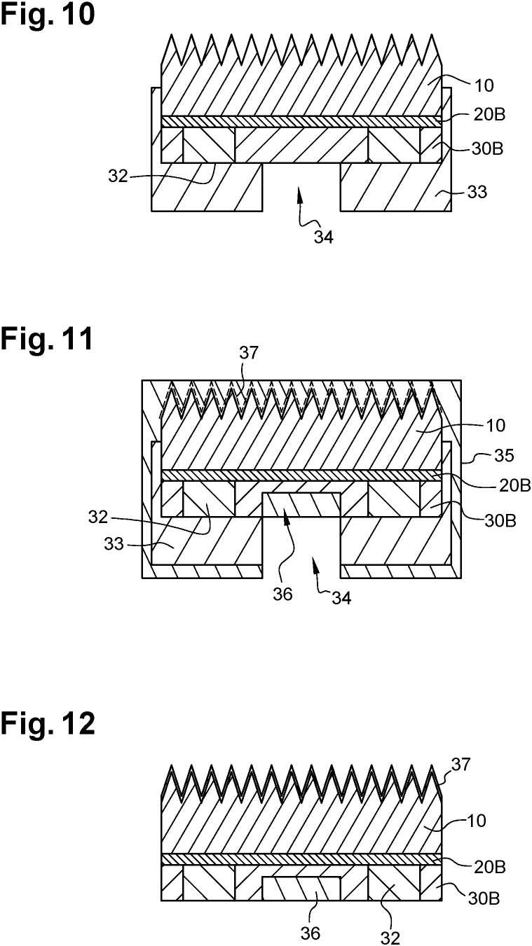

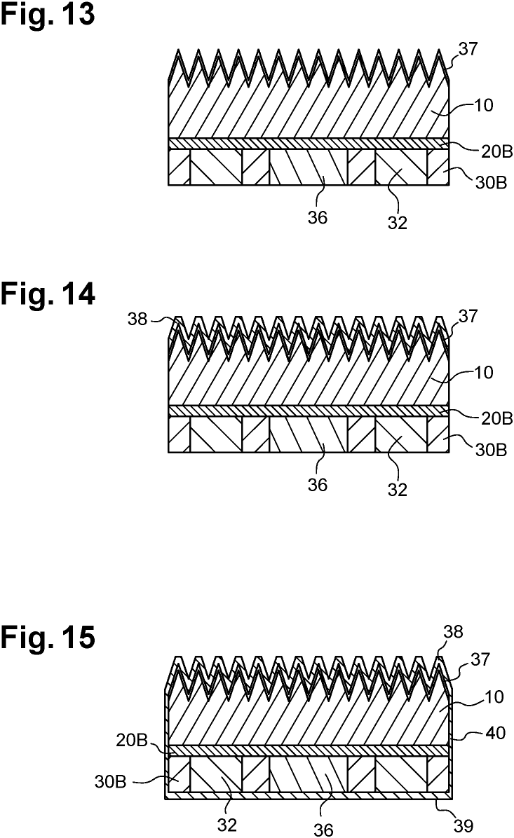

The process of manufacturing the contact of the solar cell shown in FIG. 1 may comprises:
preparation (FIG. 2) of the semiconductor substrate 10;
formation (FIG. 3) of a tunnel oxide layer 20F on a front side 101 of the substrate 10 and of another tunnel oxide layer 20B on a back side 103 of the substrate 10;
formation of a semiconductor layer 30F on the front side of layer 20F and another semiconductor layer 30B on the back side of layer 20B;
formation (FIG. 4) of a layer 31 on the back side of layer 30B, made of a doped layer, which is formed over the entire layer 30B, and an undoped layer formed over the entire doped layer. The doped layer include a first-type (p or n) conductive dopant;
formation (FIG. 5) of openings 310 in layer 31 using, for example, a wet etching process;
formation (FIG. 6) of areas 32 in the layer 30B by the thermal diffusion of dopants of layer 31 in the layer 30B by using a laser;
deposition (FIG. 7) of a masking layer 33 all around the structure;
removal (FIG. 8) of the masking layer 33 from the front side of the structure and more precisely from the front side of layer 30F and from the lateral sides of layer 30F, layer 20F and a part of the substrate 10;
removal (FIG. 9) of layer 20F and layer 30F and texturing process of the front side of layer 30F;
formation (FIG. 10) of openings 34 in the masking layer 33;
treatment (FIG. 11) under a gas atmosphere 35 containing a second-type conductive dopant in order to form an area 36 in the layer 30B and a layer 37 on the front side of the substrate 10;
removal (FIG. 12) of the masking layer 33;
thermal treatment (FIG. 13) in order to diffuse the dopant of the area 36 in all the depth of layer 30B;
formation (FIG. 14) of a passivation and anti-reflection film 38 in the front side of layer 37;
formation (FIG. 15) of a passivation film 39 in the back side of the structure and a passivation film 40 in lateral sides of the structure; and
formation (FIG. 16) of electrodes 41 on the back side of the structure by a step of wet etch of the layer 39 and a step of metal deposition.

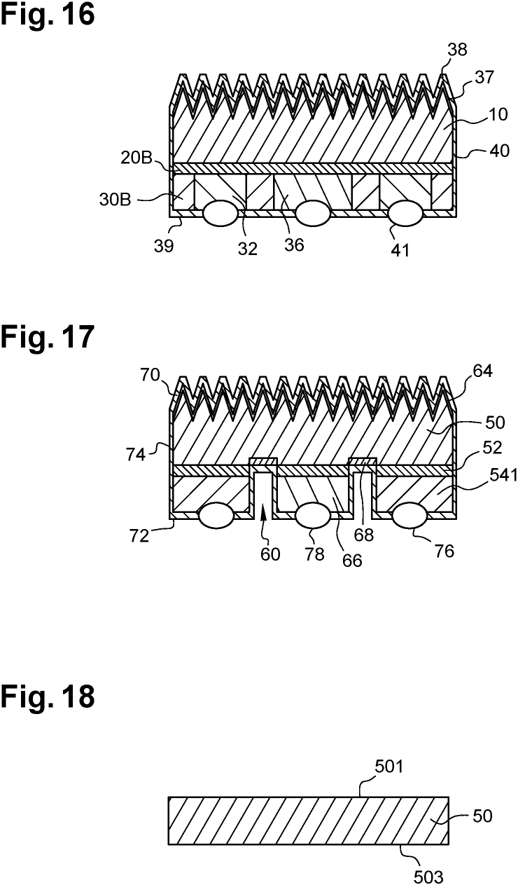

FIG. 17 is a sectional view illustrating a solar cell in accordance with an embodiment of the present description.

The solar cell shown in FIG. 17 is made of a semiconductor substrate 50 having a front side portion intended to receive solar radiations during normal operation and a back side portion where metal contacts to the solar cell are formed. The solar cell has a textured front side covered by a doped layer 64.

The solar cell of FIG. 17 includes one or more regions 541 of a first-type of conductivity, such as p-type regions, and one or more regions 66 of a second-type of conductivity, such as n-type regions, formed over the back side of the substrate 50. A tunnel oxide layer 52 may be formed on the back side of the substrate 50, more precisely, between the substrate 50 and the regions 541, 66.

Metal contacts 76 and 78 are, respectively, connected to regions 541 and 66 to allow external circuits and devices to receive electrical power from the solar cell.

Solar cell of FIG. 17 may include passivation layers 70, 72, 74 to protect the structure from outside electrical damages.

Moreover, the solar cell shown in FIG. 17 may include, regions 66 and regions 541, trenches 60, between regions 66 and regions 541, and, in the substrate 50, a low depth of the substrate 68 doped with the second-type conductive dopants.

FIG. 18 illustrate a step of manufacturing a contact solar cell in accordance with the embodiment of the present description.

In the present embodiment, the substrate 50 is a semiconductor substrate, for example a silicon wafer, preferably doped with an n-type dopant such as Phosphorus (P), or a p-type dopant such as Gallium (Ga) and Boron (B).

Substrate 50 has a front side 501 and a back side 503. Front side 501 is the side of the solar cell intended to receive solar radiations. Substrate 50 is thinned to a thickness of, for example, about 240 µm using a process that also etches damages from the surfaces of the wafer (Saw Damage Etching - SDE).

FIG. 19 illustrate another step of manufacturing a contact solar cell in accordance with the embodiment of the present description.

In FIG. 19, a tunnel oxide layer 52 is formed over the back side 503 and, for example, over the front side of the substrate. Tunnel oxide layer 52 is formed in order to be thin enough to increase the probability of electrons directly tunnelling across tunnel oxide layer 52. Tunnel oxide layer 52 may have a thickness of about 7 Angstroms to about 20 Angstroms. In one embodiment, tunnel oxide layer 52 has a thickness of about 10 Angstroms. Tunnel oxide layer 52 may be formed by, for example, thermal growth or chemical deposition (e.g., plasma enhanced chemical vapor deposition (PECVD) or low pressure chemical vapor deposition (LPCVD)). Tunnel oxide layer 52 may be formed using an ozone oxidation process, which involves dipping substrate 50 in a bath comprising ozone suspended in deionized water. For example, substrate 50 may first undergo a wet etch using potassium hydroxide to thin substrate 50, then a rinse-clean cycle, then the ozone oxidation process to form tunnel oxide layer 52 all in the same equipment. During the ozone oxidation process, a layer of tunnel oxide grows on both sides of substrate 50.

According to an alternative embodiment, tunnel oxide layer 52 may also be formed using other processes without detracting from the merits of the present description.

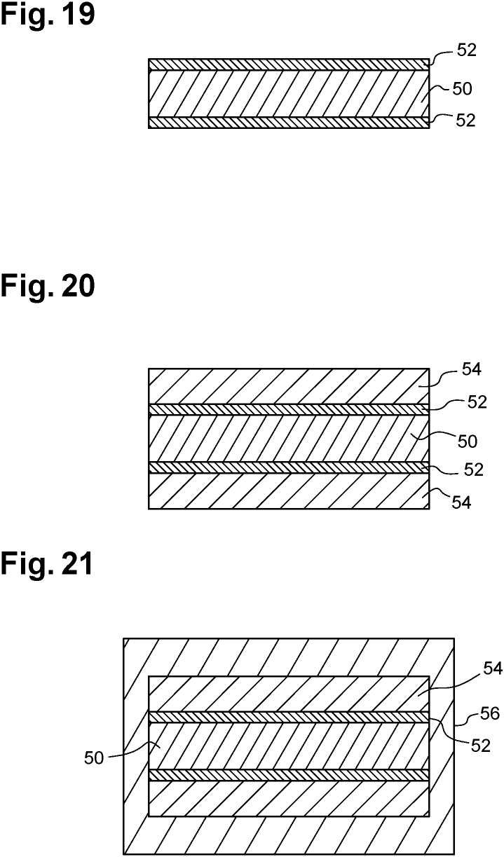

FIG. 20 illustrate another step of manufacturing a contact solar cell in accordance with the embodiment of the present description.

In FIG. 20, a doped layer 54, for example a p doped polysilicon layer, is formed over tunnel oxide layer 52.

Polysilicon layer 54 may have a thickness of about 2000 Angstroms. Polysilicon layer may be deposited on tunnel oxide 52 by PECVD or LPCVD using boron trichloride (BCI₃) or diborane (B₂H₆) with silane (SiH₄) .

FIG. 21 illustrate another step of manufacturing a contact solar cell in accordance with the embodiment of the present description.

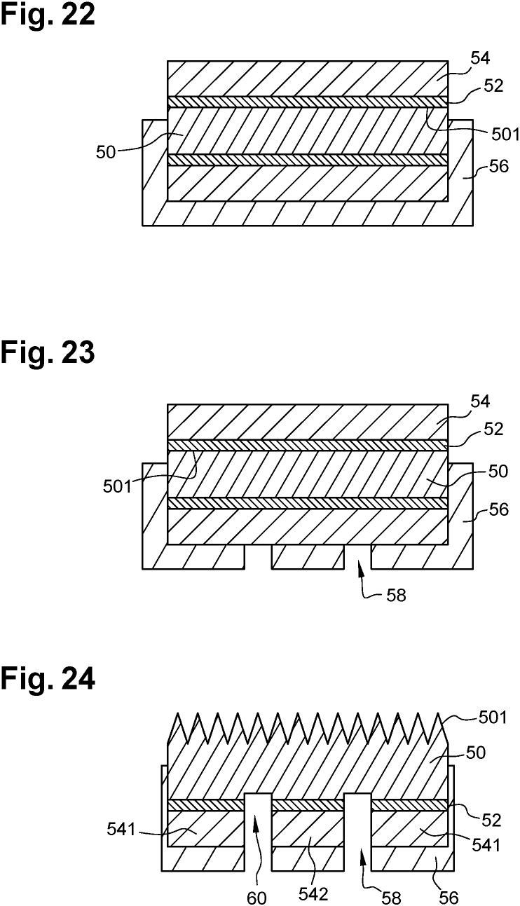

In FIG. 21, a masking layer 56 is formed over the layer 54, on the front side and on the back side, in order to fully wrap the structure of FIG. 20. Masking layer 56 will be used in a subsequent etch and laser process (FIGS. 23 and 24) exposing portions of layer 54. Masking layer 56 may be formed by, for example, thermal growth or chemical deposition (PECVD or LPCVD). However, various other methods may be applied to form the masking layer 56.

Masking layer 56 may be formed of a material selected for being an undoped material having no conductive dopant and for its ability of preventing the diffusion of the n conductive dopant. In one example, the masking layer 56 may be a single layer including a silicon oxide (SiOₓ), a silicon nitride (SiHₓ), a silicon oxynitride (SiOₓN_{y}), intrinsic amorphous silicon, or a silicon carbide (SiC). In particular, when the masking layer 56 is a single layer formed of a silicon carbide, the masking layer 56 may effectively prevent the diffusion of the dopant.

FIG. 22 illustrate another step of manufacturing a contact solar cell in accordance with the embodiment of the present description.

In FIG. 22, masking layer 56 is removed from the front side (from the side of front side 501 of the substrate 50) and, for example, from a part of the lateral sides of the structure.

FIG. 23 illustrate another step of manufacturing a solar cell in accordance with the embodiment of the present description.

In FIG. 23, the masking layer 56 is removed from the back side (from the back side of the substrate 50) in some areas in order to create apertures 58 through the masking layer 56 and the layer 54. In the present embodiment, two apertures 58 are made on the masking layer 56, however, the number of apertures can be different than two. Each aperture has a width of between 30 nm and 200 µm and a depth approximately equal to the thickness of the masking layer 56. The apertures 58 are, for example, made by using a laser.

FIG. 24 illustrate another step of manufacturing a contact solar cell in accordance with the embodiment of the present description.

In FIG. 24, front side 501 of substrate 50 is textured. Front side 501 may be textured using a wet etch process or another chemical process comprising, for example, potassium hydroxide and isopropyl alcohol or a solution of TMAH (Tetramethylammonium hydroxid). The wet etch process textures front side 501 with random pyramids, thereby advantageously improving solar radiation collection efficiency.

In FIG. 24, masking layer 56 is used in etching p-type dopant layer 54 and tunnel oxide layer 52. In one embodiment, the layer 54, layer 52 and the substrate 50 are patterned using a wet etch process comprising buffered hydrofluoric acid, potassium hydroxide with isopropyl alcohol or a solution of TMAH (TertraMethylAmmonium Hydroxid). The wet etch process etches portions of the layer 54, the tunnel oxide layer 52 and the substrate 50 not covered by the masking layer 56. The wet etch process etches in order to create trenches 60 which extend from the apertures 58 into the layer 54, the tunnel oxide layer 52 and the substrate 50. Trenches 60 separates regions of layer 54 in order to form regions 541 and 542 are formed in the layer 54.

In one embodiment the front surface 501 of the semiconductor substrate 50 is textured before the trenches 60 are formed

However, the embodiment is not limited thereto. Thus, the front surface 501 of the semiconductor substrate 50 may be textured after the trenches 60 are formed or in a separate process.

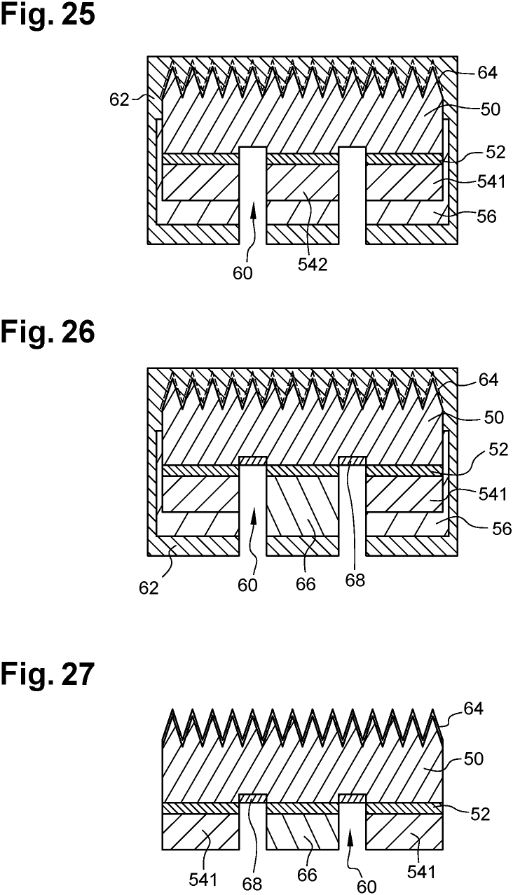

FIG. 25 illustrate another step of manufacturing a contact solar cell in accordance with the embodiment of the present description.

The structure shown in FIG. 24 is, in FIG. 25, put in a gas atmosphere 62 containing a n-type conductive dopant. The gas atmosphere 62 may be created using various gases containing the n-type conductive dopant. In one example, when the conductive dopant is phosphorus (P), the gas atmosphere 62 may include phosphoryl chloride (POCl₃).

At this time, the front surface 501 of the semiconductor substrate 50 may be doped with the n-type conductive dopant. Thereby, a front surface field 64 area may also be formed during the doping process. However, the embodiment of the present description is not limited thereto. Thus, in the doping process, an anti-diffusion film may be formed over the front surface 501 of the semiconductor substrate 50 so that no front surface field 64 area is formed in the doping process. In this instance, the front surface field area 64 may be formed in a separate process selected from among various processes including, for example, ion implantation, thermal diffusion, and laser doping.

FIG. 26 illustrate another step of manufacturing a contact solar cell in accordance with the embodiment of the present description.

FIG. 26 illustrates the doping of regions 542 in order to create regions 66. The doping process of regions 66 is made by using a laser.

Regions 68 are formed during this doping process. Field areas 64 can also be realised during this doping process, both under POCl₃.

The laser may have a wavelength of 1064 nm or less. This is because it is difficult to produce a laser having wavelength exceeding 1064 nm. That is, all of the wavelength of infrared light, ultraviolet light and visible light may be used as the laser. At this time, in one example, the laser may be a laser having wavelength within a range from 500 nm to 650 nm, that is a green laser.

FIG. 27 illustrate another step of manufacturing a contact solar cell in accordance with the embodiment of the present description.

In FIG. 27, the substrate 50 is doped by using the laser mentioned in FIG. 26. In an embodiment, the substrate 50 is doped in the same moment than the region 542 doping. At this time, mask 56 is removed and the structure leave the gas atmosphere 62.

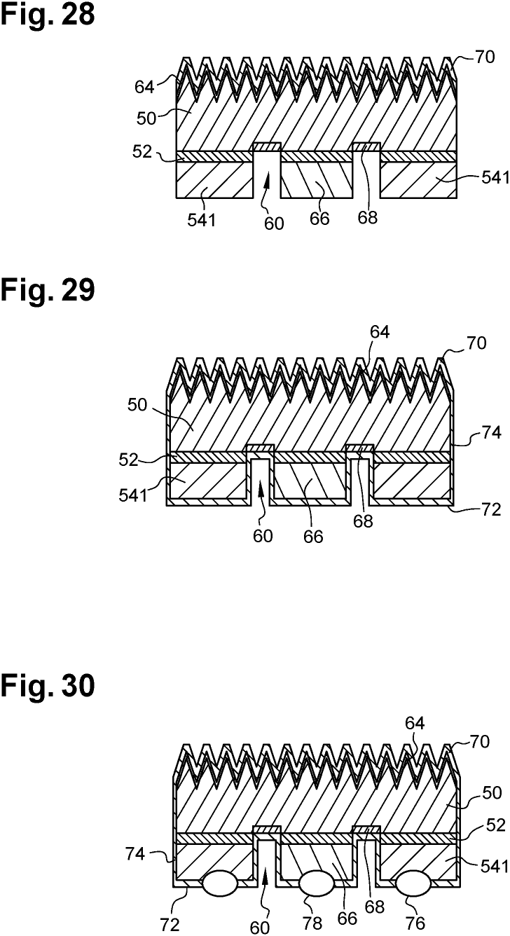

FIG. 28 illustrate another step of manufacturing a contact solar cell in accordance with the embodiment of the present description.

In FIG. 28, an insulation film 70 is formed on the front surface of the semiconductor substrate 50. Insulation film 70 includes a front surface passivation film and an anti-reflection film which are formed on the front surface of the layer 64. For example, the front surface passivation film and the anti-reflection film are formed over the entire front surface of the layer 64. The front surface passivation film and the anti-reflection film may be formed using various methods such as, for example, vacuum deposition, chemical vapor deposition, spin coating, screen printing, or spray coating. The sequence of forming the front passivation film and the anti-reflection film is not defined.

FIG. 29 illustrate another step of manufacturing a contact solar cell in accordance with the embodiment of the present description.

In FIG. 29, insulation films 72 and 74 are respectively formed on the back surface and on the lateral surface of the structure.

For example, the back surface passivation film 72 is formed over the entire back surface of the structure. The back surface passivation film 72 may be formed using various methods such as, for example, vacuum deposition, chemical vapor deposition, spin coating, screen printing, or spray coating.

FIG. 30 illustrate another step of manufacturing a contact solar cell in accordance with the embodiment of the present description.

FIG. 30 illustrates formation of first and second electrodes 76 and 78, which are respectively connected to the conductive regions 541 and 66.

The first and second electrodes 76 and 78 may be formed by applying paste, to the back surface by, for example, screen printing, and thereafter performing, for example, fire-through or laser firing contact. The back surface is etched, for example the passivation film 72 is etched, before the deposition of metal, in order to create metallizations.

An advantage of the second embodiment and implementation modes is that the tunnel oxide, doped layer and mask deposition is realised in one step contrary to the first embodiment.

An advantage of the second embodiment and implementation modes is that the manufacturing process of solar cells is shorter and cheaper than the first embodiment.

Various embodiments and variants have been described. Those skilled in the art will understand that certain features of these embodiments can be combined and other variants will readily occur to those skilled in the art.

Finally, the practical implementation of the embodiments and variants described herein is within the capabilities of those skilled in the art based on the functional description provided hereinabove.

1. A method of manufacturing a solar cell, the method comprising, in the order:
forming a tunnel oxide over, at least, one surface of a semiconductor substrate;
forming a layer doped with a first-type conductive dopant over the tunnel oxide;
forming a mask on the doped layer; and
performing, in a gas atmosphere containing a second-type conductive dopant, doping at least one first region of the doped layer using a laser.

2. A method according to claim 1, comprising forming trenches extending in the mask, the tunnel oxide and the doped layer, after the formation of the mask.

3. The method according to claim 2, wherein trenches separate the first regions of the doped layer from second regions of the doped layer.

4. The method according to claim 2 comprising forming a passivation filmover the doped layer, the passivation layer recovering the inside of trenches.

5. The method according to claim 1, wherein the gas includes phosphoryl chloride.

6. The method according to claim 1, comprising texturing of the semiconductor substrate on another surface.

7. An IBC solar cell obtained by the method according to claim 1.

8. A solar panel comprising IBC solar cells according to claim 7.
